(19) United States
(12) Patent Application Publication
(10) Pub. No.: US 2013/0305984 A1
(43) Pub. Date: Nov. 21, 2013

(54) GRAPHITE CRUCIBLE FOR SINGLE CRYSTAL PULLING APPARATUS AND METHOD OF MANUFACTURING SAME

(71) Applicants: Osamu Okada, Mitoyo-shi (JP); Yoshiaki Hirose, Mitoyo-shi (JP); Tomomitsu Yokoi, Mitoyo-shi (JP); Yasuhisa Ogita, Kanonji-shi (JP)

(72) Inventors: Osamu Okada, Mitoyo-shi (JP); Yoshiaki Hirose, Mitoyo-shi (JP); Tomomitsu Yokoi, Mitoyo-shi (JP); Yasuhisa Ogita, Kanonji-shi (JP)

(73) Assignee: TOYO TANSO CO., LTD., Osaka-shi, Osaka (JP)

(21) Appl. No.: 13/980,995

(22) PCT Filed: Jan. 30, 2010
(86) PCT No.: PCT/JP2012/051975

§ 371 Date: Jul. 22, 2013

(30) Foreign Application Priority Data
Feb. 2, 2011 (JP) 2011-020813
Feb. 2, 2011 (JP) 2011-020814

(51) Int. Cl. C30B 15/10

(52) U.S. Cl. CPC C30B 15/10
USPC 117/208; 427/230; 427/235; 427/237

(57) ABSTRACT

A graphite crucible (2) for retaining a quartz crucible (1) has a graphite crucible substrate (3) as a graphite crucible forming material, and a coating film (4) made of a carbonized phenolic resin and formed over the entire surface of the graphite crucible substrate (3). The phenolic resin is impregnated inside open pores (5) existing in a surface of the graphite crucible substrate (3). The coating film (4) may be formed only within a portion of the graphite crucible in which SiC formation can occur easily, not over the entirety of the surface of the graphite crucible. For example, it is possible to deposit the film only on the entire inner surface of the crucible. It is also possible to deposit the film only on a curved portion (sharply curved portion) of the inner surface, or only on a curved portion and a straight trunk portion.

### TECHNICAL FIELD

The present invention relates to a carbon crucible used for retaining a quartz crucible used in an apparatus for pulling a single crystal of silicon or the like by a Czochralski process (hereinafter referred to as a “CZ process”), and to a method of manufacturing the same.

### BACKGROUND ART

Single crystals of silicon or the like used for manufacturing ICs and LSIs are usually manufactured by a CZ process. The CZ process is as follows. Polycrystalline silicon is put in a high-purity quartz crucible, and while rotating the quartz crucible at a predetermined speed, the polycrystalline silicon is heated by a heater to melt the polycrystalline silicon. A seed crystal (silicon single crystal) is brought into contact with the surface of the melt, and is gradually pulled up while being rotated at a predetermined speed to solidify the polycrystalline silicon melt, whereby a silicon single crystal is grown.

However, the quartz crucible softens at high temperature and is insufficient in strength. For this reason, when in use, the quartz crucible is usually fitted in a graphite crucible so that the quartz crucible can be reinforced by being supported by the graphite crucible.

In a crucible apparatus having the quartz crucible and the graphite crucible as described above, the quartz crucible (SiO₂) and the graphite crucible (C) react with each other at the fitted surface where they are in contact with each other during high temperature heating, generating SiO gas. The generated SiO gas reacts with the graphite crucible. In particular, while infiltrating the inside of the open pores in the surface layer portion of the graphite crucible, it reacts with the graphite crucible (C) and gradually turns the inside of the open pores of the graphite crucible into SiC. Accordingly, when such a heat treatment is carried out repeatedly, the graphite crucible is gradually turned into SiC, so that the dimensions of the graphite crucible may be changed, or the graphite crucible may become brittle as a material and microcracks develop therein, causing the graphite crucible to break in the end.

In order to solve such a problem, it has been proposed that a protective sheet made of an expanded graphite material is interposed between the quartz crucible and the graphite crucible so as to cover the inner surface of the graphite crucible, whereby the SiC formation in the graphite crucible can be prevented to keep the life of the graphite crucible long (for example, see Patent Document 1).

### CITATION LIST

### Patent Literature

[Patent Document 1] Japanese Patent No. 2528285

### SUMMARY OF INVENTION

### Technical Problem

Nevertheless, in reality, even when the protective sheet is interposed as in the above-described conventional example, the SiC formation in the graphite crucible cannot be inhibited sufficiently.

Accordingly, there has heretofore been a need for a graphite crucible for single crystal pulling apparatus that makes it possible to prolong the life span.

The present invention has been accomplished in view of the foregoing circumstances. It is an object of the invention to provide a graphite crucible for single crystal pulling apparatus and a method of manufacturing the same that make it possible to prolong the life span.

### Solution to Problem

In order to accomplish the foregoing object, the present invention provides a graphite crucible for single crystal pulling apparatus wherein a phenolic resin impregnated in open pores existing in a surface of a graphite crucible substrate is carbonized.

With the just-described configuration, the carbonized phenolic resin that is impregnated into the inner surfaces of a large number of open pores existing in the surface of the graphite crucible substrate can effectively inhibit the reaction between C and SiO gas over the entire surface of the graphite crucible substrate, and inhibit development of the SiC formation. As a result, the service life of the graphite crucible can be prolonged.

The formation of the coating film by the carbonized phenolic resin may be only within a portion of the graphite crucible in which SiC formation can occur easily, not over the entirety of the surface of the graphite crucible. For example, it is possible to form the film only on the entire inner surface of the crucible. It is also possible to form the film only on a curved portion (sharply curved portion) of the inner surface, or only on the curved portion and a straight trunk portion.

In the present invention, it is preferable that the coating film have an average thickness of 10 μm or less. If the thickness of the coating film exceeds 10 μm, there is a risk that the coating film may be easily peeled.

The present invention also provides a method of manufacturing a graphite crucible for single crystal pulling apparatus, characterized by comprising the steps of: immersing a graphite crucible substrate in a phenolic resin solution under room temperature and normal pressure; curing the phenolic resin by taking out and heat-treating the immersed graphite crucible substrate; and carbonizing the phenolic resin by subjecting the cured phenolic resin to a further heat treatment.

The just-described configuration makes it possible to manufacture a graphite crucible in which the phenolic resin is impregnated into the inner surfaces of a large number of open pores existing in the surface of the graphite crucible substrate, so that the service life of the graphite crucible can be prolonged.

In the present invention, it is preferable that the method further comprise, prior to the curing step, the step of wiping off an excessive amount of the phenolic resin on a surface of the graphite crucible substrate.

With the just-described configuration, the surface layer of the graphite crucible substrate is coated with a necessary amount of the phenolic resin. Therefore, the SiC formation can be effectively prevented. Moreover, it is possible to obtain a graphite crucible that does not change much in dimensions even after the heat treatment.

In the present invention, it is preferable that the phenolic resin solution have a viscosity of from 100 mP·s (18° C.) to 400 mP·s (18° C.).

With the just-described configuration, the phenolic resin can be impregnated sufficiently in the open pores in the graphite crucible substrate. Moreover, an appropriate amount of the resin can be coated easily when wiping off an excessive amount of the phenolic resin on the surface of the graphite crucible substrate. Furthermore, the resin content is prevented from being squirted out after the heat treatment.

In the present invention, it is preferable that the method further comprise, subsequent to the curing step, the step of performing a heat treatment at a temperature equal to or higher than a service temperature.

With the just-described configuration, heat-treating at a temperature equal to or higher than the service temperature serves to stabilize the bonding of the coating film with the substrate, so the film is unlikely to peel off.

In the present invention, it is preferable that the method further comprise, subsequent to the curing step, the step of refining the graphite crucible substrate on which a coating film of the phenolic resin is formed, by heat-treating the graphite crucible substrate under a halogen gas atmosphere.

With the just-described configuration, the amount of impurities produced from the graphite crucible can be reduced, so a high quality metal single crystal can be obtained.

In order to accomplish the foregoing object, the present invention also provides a graphite crucible for single crystal pulling apparatus, wherein a coating film of pyrocarbon is formed on an entirety of or a portion of a surface of a graphite crucible substrate, and the coating film is formed so as to reach an inner surface of open pores existing in the surface of the graphite crucible substrate.

Herein, pyrocarbon (PyC) refers to a high-purity and high-crystallinity graphitized substance obtained by thermally decomposing a hydrocarbon, for example, a hydrocarbon gas or a hydrocarbon compound having 1 to 8 carbon atoms, particularly 3 carbon atoms, to infiltrate and deposit into a deep layer portion of a substrate.

With the just-described configuration, the pyrocarbon is deposited and filled over the inner surfaces of a large number of open pores existing in the surface of the graphite crucible substrate. As a result, the reaction between C and SiO gas can be effectively inhibited over the entire surface of the graphite crucible substrate, and development of the SiC formation can be inhibited. As a result, the service life of the graphite crucible can be prolonged.

It should be noted that the coating film of pyrocarbon may be formed only within a portion of the graphite crucible in which SiC formation can occur easily, not over the entirety of the surface of the graphite crucible. For example, it is possible to deposit the film only on the entire inner surface of the crucible. It is also possible to deposit the film only on a curved portion (sharply curved portion) of the inner surface, or only on the curved portion and a straight trunk portion.

In the present invention, it is preferable that the pyrocarbon coating film have an average thickness of 100 μm or less. If the thickness exceeds 100 μm, the cost will become high, and an extremely long time treatment will become necessary to form a pyrocarbon coating film with 100 μm or thicker, so the production efficiency decreases.

In the present invention, it is preferable that the coating film be formed by a CVI method.

Herein, the CVI (Chemical Vapor Infiltration) method refers to a technique for infiltrating and depositing the above-described pyrocarbon (PyC), wherein the reaction process may be conducted as follows: a nitrogen gas or a hydrogen gas is used for adjusting the concentration of a hydrocarbon or a hydrocarbon compound; the hydrocarbon concentration is set at 3% to 30%, preferably 5% to 15%; and the total pressure is set at 100 Torr, preferably 50 Torr or less. When such a process is carried out, the hydrocarbon forms a giant carbon compound on or near the substrate surface by, for example, dehydrogenation, thermal decomposition, or polymerization, and the giant carbon compound is deposited on the graphite crucible substrate; and further the dehydrogenation reaction proceeds, finally forming a dense PyC film from the surface of the graphite crucible substrate to the inside thereof.

The temperature range of the deposition is usually wide, from 800° C. to 2500° C., but in order to deposit the film into a deep portion of the graphite crucible substrate, it is desirable that the PyC be deposited in a relatively low temperature region of 1300° C. or lower. In addition, it is suitable that the deposition time should be set at a long time, at 50 hours, or preferably 100 hours or longer, in order to form a thin PyC of, for example, 100 μm or less. Also, in order to enhance the efficiency in the deposition of pyrocarbon, it is possible to use what is called an isothermal method, a thermal gradient method, a pressure gradient method, a pulse method, or the like, as appropriate. For reference, the CVD (Chemical Vapor Deposition) method is a technique of directly depositing decomposed carbon into the texture. Therefore, unlike the CVI method, the CVD method cannot cause decomposed carbon to infiltrate and form a film inside a substrate, and it can merely deposit thick pyrocarbon within a short time.

The present invention also provides a method of manufacturing a graphite crucible for single crystal pulling apparatus, which comprises the step of forming a coating film of pyrocarbon by a CVI method so that the coating film of pyrocarbon is formed on an entirety of or a portion of a surface of a graphite crucible substrate and that the coating film is formed so as to reach an internal surface of open pores existing in a surface of the graphite crucible substrate.

The just-described configuration makes it possible to manufacture a graphite crucible in which the pyrocarbon is impregnated into the inner surfaces of a large number of open pores existing in the surface of the graphite crucible substrate, so that the service life of the graphite crucible can be prolonged.

In the present invention, it is preferable that the method further comprise the step of refining the graphite crucible substrate on which the coating film of the pyrocarbon is formed, by heat-treating the graphite crucible substrate under a halogen gas atmosphere. The amount of impurities produced from the graphite crucible can be reduced, so a high quality metal single crystal can be obtained.

### Advantageous Effects of Invention

According to the present invention, the carbonized phenolic resin impregnated into the inner surfaces of a large number of open pores existing in the surface of the graphite crucible substrate can effectively inhibit the reaction between C and SiO gas over the entire surface of the graphite crucible substrate, thus inhibiting development of the SiC formation. As a result, the service life of the graphite crucible can be prolonged.

Moreover, according to the present invention, the pyrocarbon is deposited and filled over the inner surfaces of a large number of open pores existing in the surface of the graphite crucible substrate. As a result, the reaction between C and SiO gas can be effectively inhibited over the entire surface of the graphite crucible substrate, and development of the SiC formation can be inhibited. As a result, the service life of the graphite crucible can be prolonged.

### BRIEF DESCRIPTION OF DRAWINGS

FIG. 1 is a vertical cross-sectional view illustrating a graphite crucible for single crystal pulling apparatus according to Embodiment 1.

FIG. 2 shows partially-enlarged cross-sectional views each illustrating a surface of a graphite crucible substrate according to Embodiment 1.

FIG. 3 is a schematic cross-sectional view illustrating a graphite mold used for fabricating synthetic quartz.

FIG. 4 is a vertical cross-sectional view illustrating a graphite crucible for single crystal pulling apparatus according to Embodiment 2.

FIG. 5 shows partially-enlarged cross-sectional views each illustrating a surface of a graphite crucible substrate according to Embodiment 2.

FIG. 6 is a view illustrating the position where test sample C is taken in the examples corresponding to Embodiment 1.

FIG. 7 is a graph illustrating the distribution states of pores (open pores) before and after a SiC formation reaction test in an example corresponding to Embodiment 1.

FIG. 8 is a photograph illustrating the condition of test sample A (present invention treated product) after ashing subsequent to a SiC formation reaction test in an example corresponding to Embodiment 1.

FIG. 9 is a photograph illustrating the condition of test sample B (present invention treated product) after ashing subsequent to a SiC formation reaction test in an example corresponding to Embodiment 1.

FIG. 10 is a photograph illustrating the condition of test sample A (non-treated product) after ashing subsequent to a SiC formation reaction test in an example corresponding to Embodiment 1.

FIG. 11 is a photograph illustrating the condition of test sample B (non-treated product) after ashing subsequent to a SiC formation reaction test in an example corresponding to Embodiment 1.

FIG. 12 is a SEM photograph of test sample A (present invention treated product) subsequent to a SiC formation reaction test in an example corresponding to Embodiment 1.

FIG. 13 is a SEM photograph of test sample B (present invention treated product) subsequent to a SiC formation reaction test in an example corresponding to Embodiment 1.

FIG. 14 is a SEM photograph of test sample C (present invention treated product) subsequent to a SiC formation reaction test in an example corresponding to Embodiment 1.

FIG. 15 is a SEM photograph of test sample A (non-treated product) subsequent to a SiC formation reaction test in an example corresponding to Embodiment 1.

FIG. 16 is a SEM photograph of test sample C (non-treated product) subsequent to a SiC formation reaction test in an example corresponding to Embodiment 1.

FIG. 17 is a view illustrating the position where test sample C1 is taken in Examples corresponding to Embodiment 2.

FIG. 18 is a graph illustrating the distribution states of pores (open pores) before and after a SiC formation reaction test in an example corresponding to Embodiment 2.

FIG. 19 is a photograph illustrating the condition of test sample A1 (present invention treated product) after ashing subsequent to a SiC formation reaction test in an example corresponding to Embodiment 2.

FIG. 20 is a photograph illustrating the condition of test sample B1 (present invention treated product) after ashing subsequent to a SiC formation reaction test in an example corresponding to Embodiment 2.

FIG. 21 is a photograph illustrating the condition of test sample A1 (non-treated product) after ashing subsequent to a SiC formation reaction test in an example corresponding to Embodiment 2.

FIG. 22 is a photograph illustrating the condition of test sample B1 (non-treated product) after ashing subsequent to a SiC formation reaction test in an example corresponding to Embodiment 2.

FIG. 23 is a SEM photograph of test sample A1 (present invention treated product) subsequent to a SiC formation reaction test in an example corresponding to Embodiment 2.

FIG. 24 is a SEM photograph of test sample B1 (present invention treated product) subsequent to a SiC formation reaction test in an example corresponding to Embodiment 2.

FIG. 25 is a SEM photograph of test sample C1 (present invention treated product) subsequent to a SiC formation reaction test in an example corresponding to Embodiment 2.

FIG. 26 is a SEM photograph of test sample A1 (non-treated product) subsequent to a SiC formation reaction test in an example corresponding to Embodiment 2.

FIG. 27 is a SEM photograph of test sample C1 (non-treated product) subsequent to a SiC formation reaction test in an example corresponding to Embodiment 2.

### DESCRIPTION OF EMBODIMENTS

Hereinbelow, the present invention will be described based on the preferred embodiments. It should be noted that the present invention is not limited to the following embodiments.

### Embodiment 1

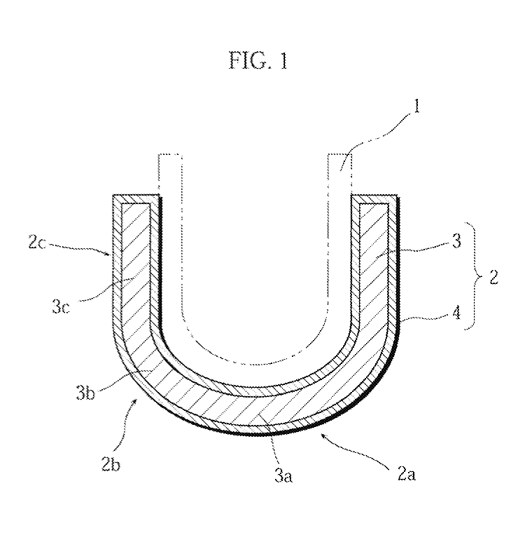

FIG. 1 is a vertical cross-sectional view for illustrating one example of a graphite crucible for single crystal pulling apparatus according to Embodiment 1. A graphite crucible 2 for retaining a quartz crucible 1 includes a graphite crucible substrate 3 as a graphite crucible forming material, and a coating film 4 made of a carbonized phenolic resin and formed over the entire surface of the graphite crucible substrate 3 (hereinafter the coating film may also be referred to simply as a “phenolic resin coating film”). The graphite crucible substrate 3 used here should have a bulk density of 1.70 Mg/m³ or higher, a flexural strength of 30 MPa or higher, and a Shore hardness of 40 or higher as its characteristics, in order to ensure necessary mechanical strength for a crucible and also taking into consideration readiness of the phenolic resin impregnation. The carbonized substance that constitutes the coating film 4 may be a graphitized substance the entirety or a portion of which has been subjected to a graphitization process.

Here, the shape of the graphite crucible 2 is generally in a cup-like shape, formed by a bottom portion 2a, a curved portion (sharply curved portion) 2b curved upward and connected to the bottom portion 2a, and a straight trunk portion 2c extending upward straightly and being connected to the curved portion 2b. The shape of the graphite crucible substrate 3 corresponds to the shape of the graphite crucible 2, and it is formed by a bottom portion 3a, a curved portion (sharply curved portion) 3b, and a straight trunk portion 3c. In the graphite crucible substrate 3 with such a configuration, the phenolic resin coating film may be formed either over the entirety of the surface of the graphite crucible substrate 3 or only within a portion thereof in which SiC formation can occur easily. For example, it is possible to deposit the film only on the entire inner surface of the crucible. It is also possible to deposit the film only on the curved portion (sharply curved portion) 3b of the inner surface, or only on the curved portion 3b and the straight trunk portion 3c.

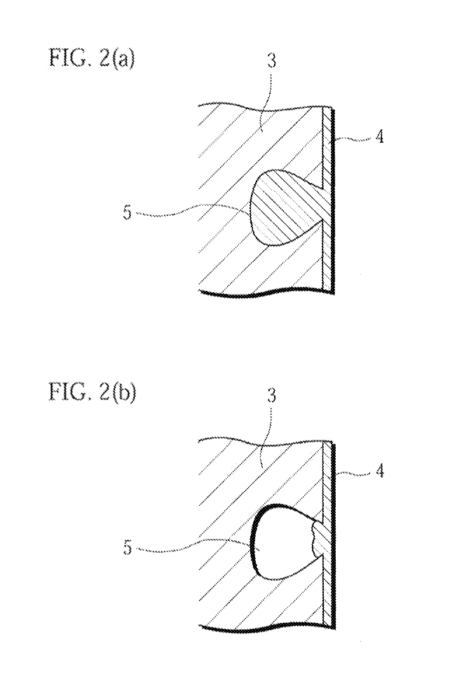

Next, the condition of the graphite crucible substrate 3 whose surface is coated by the phenolic resin coating film 4 will be described with reference to FIG. 2. FIG. 2 shows partially-enlarged cross-sectional views illustrating a surface of the graphite crucible substrate 3 according to Embodiment 1. FIG. 2(a) schematically shows a condition in which the phenolic resin coating film 4 is formed in a desirable manner over the entire surface of the graphite crucible substrate 3, and FIG. 2(b) schematically shows the condition in which the formation thereof is undesirable. The graphite crucible substrate 3 has very small pores in its surface which are called open pores 5. As illustrated in the figure, the open pores 5 form recesses in the surface. For this reason, the surface area of the graphite crucible substrate 3 is greater than that is apparently observed. So, the recess that has a small entrance but has a large internal space as shown in the figure needs to be covered by impregnating the phenolic resin into the inside of the recess as shown in FIG. 2(a).

For example, when the impregnated phenolic resin covers only the opening portion of the open pore 5 and cannot fill the inside thereof as illustrated in FIG. 2(b), cracks may be caused at the just-mentioned opening portion, which is instable in terms of strength, causing the inside portion that is not coated with the phenolic resin to be exposed to the outside in which SiO gas exists. For this reason, in the present invention, the phenolic resin impregnation is carried out under the viscosity, the immersing conditions, and the curing conditions of the phenolic resin solution as follows.

The graphite crucible with the above-described configuration was produced in the following manner.

A graphite crucible substrate was immersed in a phenolic resin solution having a viscosity of from 100 mP·s (18° C.) to 400 mP·s (18° C.) under room temperature and normal pressure for 12 hours or longer. The immersed graphite crucible substrate was taken out and heat-treated to cure the phenolic resin, and the cured phenolic resin was subjected to a further heat treatment to carbonize the phenolic resin.

It is preferable that, prior to the curing step, an excessive amount of the phenolic resin on a surface of the graphite crucible substrate be wiped off. By wiping off the phonolic resin, the surface layer of the graphite crucible substrate is coated with a necessary amount of the phenolic resin. Therefore, the SiC formation can be effectively prevented. Moreover, it is possible to obtain a graphite crucible that does not change much in dimensions even after the heat treatment.

It is also preferable that, subsequent to the curing step, the graphite crucible substrate on which the coating film of the phenolic resin has been formed be heat-treated at a temperature equal to or higher than a service temperature. The reason is that heat-treating at a temperature equal to or higher than the service temperature serves to stabilize the bonding of the coating film with the substrate, so the film is unlikely to peel off.

It is also preferable that, subsequent to the curing step, the graphite crucible substrate on which the coating film of the phenolic resin is formed be refined by heat-treating the graphite crucible substrate under a halogen gas atmosphere. The reason is that the amount of impurities produced from the graphite crucible can be reduced, so a high quality metal single crystal can be obtained.

In the present embodiment, the above-described phenolic resin impregnating-curing-carbonizing treatment made it possible to obtain a graphite crucible coated with a coating film made of the carbonized phenolic resin that is sufficiently impregnated into the inside of the substrate.

Thus, the carbonized phenolic resin that is impregnated into the inner surfaces of a large number of open pores existing in the surface of the graphite crucible substrate can effectively inhibit the reaction between C and SiO gas over the entire surface of the graphite crucible substrate, and inhibit development of the SiC formation. As a result, the service life of the graphite crucible can be prolonged.

It should be noted that the graphite crucible coated with the phonolic resin should preferably be refined by heat-treating the graphite crucible substrate under a halogen gas atmosphere. The reason is that the amount of impurities produced from the graphite crucible can be reduced, so a high quality metal single crystal can be obtained.

### Other Embodiments

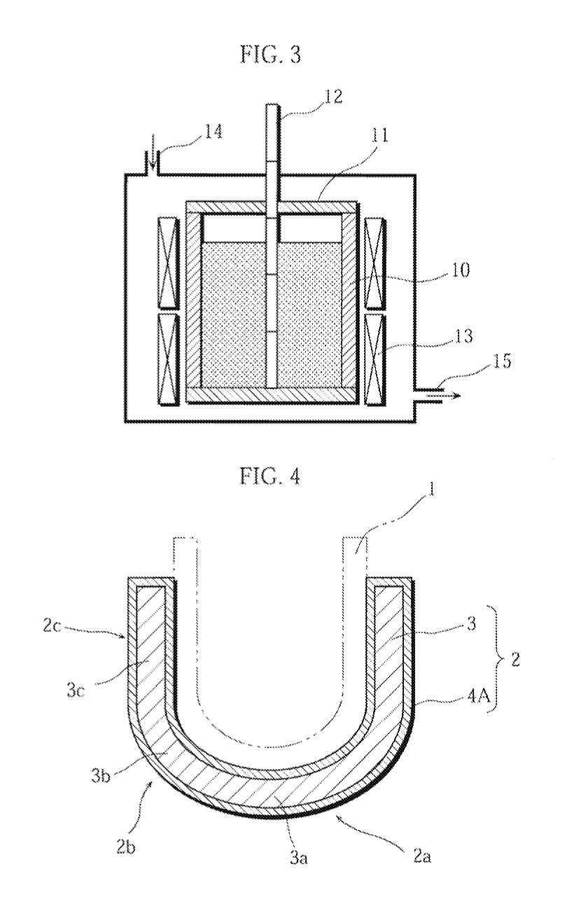

In the foregoing embodiment 1, the graphite crucible for single crystal pulling apparatus is the subject of the surface treatment. However, it is also possible to form a coating film made of carbonized phenolic resin on the surface of graphite members used for fabricating synthetic quartz, such as a graphite mold 10, a graphite lid 11, and the like used for fabricating synthetic quartz as illustrated in FIG. 3, by using the phenolic resin impregnating-curing-carbonizing treatment as in Embodiment 1. A conventional problem with the graphite member molds and lids used for fabricating synthetic quartz has been that, when they are in contact with synthetic quartz, the resulting SiO₂ gas promotes SiC formation, which causes dimensional changes and weakening of the material, leading to formation of microcracks and finally fractures. However, by forming a coating film of carbonized phenolic resin on the surface by the phenolic resin impregnating-curing-carbonizing treatment, the SiC formation can be inhibited, and a longer life span can be obtained. Note that in FIG. 3, reference numeral 12 indicates a rod-shaped material, reference numerals 13 indicates a heater, reference numeral 14 indicates an inert gas introducing port, and reference numeral 15 indicates a gas exhaust port.

### Embodiment 2

FIG. 4 is a vertical cross-sectional view for illustrating one example of a graphite crucible for single crystal pulling apparatus according to Embodiment 2. A graphite crucible 2 for retaining a quartz crucible 1 includes a graphite crucible substrate 3 as a graphite crucible forming material, and a pyrocarbon coating film 4A formed over the entire surface of the graphite crucible substrate 3. The graphite crucible substrate 3 used here should have a bulk density of 1.65 Mg/m³ or higher, a flexural strength of 30 MPa or higher, and a Shore hardness of 40 or higher as its characteristics, in order to ensure necessary mechanical strength for a crucible and also taking into consideration readiness of the deposition of pyrocarbon.

Here, the shape of the graphite crucible 2 is generally in a cup-like shape, formed by a bottom portion 2a, a curved portion (sharply curved portion) 2b curved upward and connected to the bottom portion 2a, and a straight trunk portion 2c extending upward straightly and being connected to the curved portion 2b. The shape of the graphite crucible substrate 3 corresponds to the shape of the graphite crucible 2, and it is formed by a bottom portion 3a, a curved portion (sharply curved portion) 3b, and a straight trunk portion 3c. In the graphite crucible substrate 3 with such a configuration, the pyrocarbon coating film may be formed either over the entirety of the surface of the graphite crucible substrate 3 or only within a portion thereof in which SiC formation can occur easily. For example, it is possible to deposit the film only on the entire inner surface of the crucible. It is also possible to deposit the film only on the curved portion (sharply curved portion) 3b of the inner surface, or only on the curved portion 3b and the straight trunk portion 3c.

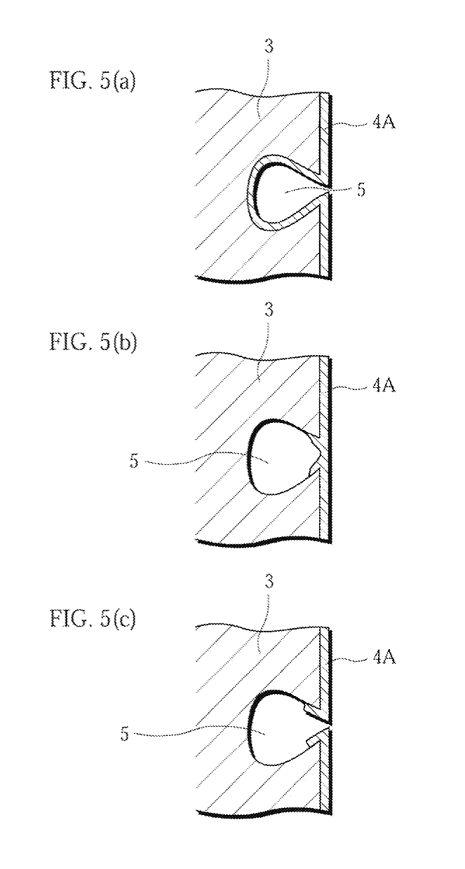

Next, the condition of the graphite crucible substrate 3 whose surface is coated by the pyrocarbon coating film 4A will be described with reference to FIG. 5. FIG. 5 shows partially-enlarged cross-sectional views illustrating a surface of the graphite crucible substrate 3 according to Embodiment 2. FIG. 5(a) schematically shows a condition in which the pyrocarbon coating film 4A is formed in a desirable manner over the entire surface of the graphite crucible substrate 3, and FIGS. 5(b) and 5(c) schematically show the condition in which the formation thereof is undesirable. The graphite crucible substrate 3 has very small pores in its surface which are called open pores 5. The open pores 5 form recesses in the surface. For this reason, the surface area of the graphite crucible substrate 3 is greater than that is apparently observed. So, for the recess that has a small entrance but has a large internal space as shown in the figure, it is necessary that even the inside of the recess needs to be covered sufficiently by the pyrocarbon film as shown in FIG. 5(a).

When the coating film is formed within a short time as in the CVD method, only the opening of the open pore is covered as shown in FIG. 5(b), and the inside thereof cannot be coated sufficiently. In this case, there is a risk that cracks may be caused at the just-mentioned opening portion, which is instable in terms of strength, causing the inside portion that is not coated with the pyrocarbon film to be exposed to the outside in which SiO gas exists. Or, even though the opening portion of the open pore 5 may not be closed, the inside of the open pore 5 cannot be coated sufficiently as shown in FIG. 5(c), and the portion that is not coated with the pyrocarbon film is exposed to the outside in which SiO gas exists, as in the just-described case. Accordingly, in order to sufficiently coat the graphite crucible substrate 3 in which a large number of open pores exist in its surface, it is necessary to slow down the deposition rate of the pyrocarbon film so that the pyrocarbon film can be deposited into the inside of the open pores. From such a viewpoint, it is desirable that the deposition rate of the pyrocarbon film be 0.2 μm/h or lower. The above-described CVI method is suitable for obtaining a thin pyrocarbon film with such a slow deposition rate.

In the present embodiment, the use of the above-described CVI method made it possible to obtain a graphite crucible coated with a pyrocarbon coating film that is sufficiently impregnated into the inside of the substrate.

Thus, the pyrocarbon is deposited and filled over the inner surfaces of a large number of open pores existing in the surface of the graphite crucible substrate. As a result, the reaction between C and SiO gas can be effectively inhibited over the entire surface of the graphite crucible substrate, and development of the SiC formation can be inhibited. As a result, the service life of the graphite crucible can be prolonged.

It should be noted that the graphite crucible coated with the pyrocarbon coating film should preferably be refined by heat-treating the graphite crucible substrate under a halogen gas atmosphere. The reason is that the amount of impurities produced from the graphite crucible can be reduced, so a high quality metal single crystal can be obtained.

### Other Embodiments

In the foregoing embodiment 2, the graphite crucible for single crystal pulling apparatus is the subject of the surface treatment. However, it is also possible to form a pyrocarbon coating film on the surface of graphite members used for fabricating synthetic quartz, such as a graphite mold 10, a graphite lid 11, and the like used for fabricating synthetic quartz as illustrated in FIG. 3, by using the CVI method as in Embodiment 2. A conventional problem with the graphite member molds and lids used for fabricating synthetic quartz has been that, when they are in contact with synthetic quartz, the resulting SiO₂ gas promotes SiC formation, which causes dimensional changes and weakening of the material, leading to formation of microcracks and finally fractures. However, by forming a pyrocarbon coating film on the surface by the CVI method, the SiC formation can be inhibited, and a longer life span can be obtained.

### EXAMPLES

Hereinbelow, the present invention will be described in detail by examples. It should be noted that the present invention is in no way limited to the following examples.

### Examples Corresponding to Embodiment 1

### Test Example 1

Dimensional changes were investigated for the following test samples.

(Test Sample)

A graphite material was surface-treated by the same phenolic resin impregnating-curing-carbonizing treatment as described in the foregoing embodiment 1. For two kinds of graphite materials, the surface-treated graphite material and a non-treated graphite material, samples with the following shape were prepared for testing.

Divided pieces of 3-piece graphite crucible: 1 piece for each

Hereinbelow, a divided piece using the surface-treated graphite material is referred to as a present invention treated product, and a divided piece using the non-treated graphite material is referred to as a non-treated product.

(Phenolic Resin Impregnating-Curing-Carbonizing Treatment)

The phenolic resin impregnating and curing treatment was carried out in the following manner.

The viscosity of the phenolic resin solution used: 195 mP·s (18° C.)

Immersing conditions: Test samples were immersed in the just-mentioned phenolic resin solution at room temperature and normal pressure for 24 hours.

Curing conditions: The temperature was elevated to 200° C. gradually so as not to foam, and thereafter kept at 200° C. for curing.

Note that the test samples after curing was heated under a halogen gas atmosphere at 2000° C. to perform a refining process (which corresponds to the carbonizing treatment for the phenolic resin).

(Test Results)

The dimensional changes in height, inner diameters at 50 mm and 150 mm from the upper end of the crucible, and radius of the sharply curved portion were investigated for the present invention treated product and the non-treated product. The results are shown in Table 1.

TABLE 1

| | Non treated | | | |
|---|---|---|---|---|
| | product | Present invention treated product | | |
| | Size | Size | Variation | Change ratio |
| | mm | mm | mm | % |
| Height | 330.01 | 330.18 | 0.17 | 0.05 |
| Inner diameter | 459.08 | 459.32 | 0.24 | 0.05 |
| (50 mm from | | | | |
| upper end of crucible) | | | | |
| Inner diameter | 459.12 | 459.28 | 0.16 | 0.04 |
| (150 mm from | | | | |
| upper end of crucible) | | | | |
| Side face sharply | 120.00 | 120.00 | 0 | 0 |
| curved portion (radius) | | | | |

(Evaluation of the Test Results)

As is clear from Table 1, it was confirmed that the present invention treated product shows extremely small dimensional changes and that there is no problem at all in practical use.

### Test Example 2

A SiC formation reaction test was conducted for the following test samples to investigate changes in their physical properties (bulk density, hardness, electrical resistivity, flexural strength, and pore (open pore) distribution) before and after the SiC reaction.

(Test Sample)

Two kinds of samples, a present invention treated product and a non-treated product that were the same as those in Test Example 1 except for their shapes, were prepared as the test samples.

The samples with the following shapes were used as the test samples.

Rod-shaped sample with dimensions 10×10×60 (mm): Hereinbelow, this rod-shaped sample is referred to as test sample A.

Plate-shaped sample with dimensions 100×200×20 (mm): Hereinbelow, this plate-shaped sample is referred to as test sample B.

A cut-out piece obtained by cutting out a test specimen with dimensions 100×20×thickness 20 (mm) from test sample B: (as illustrated in FIG. 6, out of six surfaces thereof, four surfaces are coated surfaces, and the remaining two surfaces are non-coated surfaces): Hereinbelow, this cut-out piece is referred to as test sample C.

Test samples A and B are also used as the samples for later-described Test Examples 3 and 4, in addition to for this Test Example 2, and test sample C is used only for the observation by scanning electron microscope (SEM) in the later-described Test Example 4.

Of test samples A to C, ones that are surface-treated by the phenolic resin impregnating-curing-carbonizing treatment are referred to as present invention treated products, and ones that are not surface-treated are referred to as non-treated products.

(SiC Formation Reaction Test)

Test samples A to C were subjected to a high-temperature heat treatment with synthetic quartz (high purity SiO₂) to compare SiC formation reactivity. The specific conditions in this case are as follows.

Treating furnace: Vacuum furnace

Treatment temperature: 1600° C.

Furnace internal pressure: 10 Torr

Treatment gas: Ar 1 mL/min

Treatment time Retained for 8 hours

Treatment method: Test samples are buried in synthetic quartz powder and heat-treated.

(Test Results)

The physical properties (bulk density, hardness, electrical resistivity, and flexural strength) were studied before and after the surface treatment. The results of the measurement for test sample A are shown in Table 2, and the results of the measurement for test sample B are shown in Table 3. The results of the measurement for pore (open pore) distribution are shown in FIG. 5.

TABLE 2

| | Present invention | |
|---|---|---|
| | treated product | Non-treated product |
| Bulk density | 1.79 | 1.74 |
| (Mg/m³) | | |
| Hardness | 62 | 55 |
| (HSD) | | |
| Electrical resistivity | 12.5 | 14.0 |
| (μΩm) | | |
| Flexural strength | 52 | 40 |
| (MPa) | | |

TABLE 3

| | Present invention treated product | Non-treated product |
|---|---|---|
| Bulk density | 1.76 | 1.75 |
| (Mg/m³) | | |

(Evaluation of the Test Results)

As is clear from Tables 2 and 3, the present invention treated products show improvements in all of bulk density, hardness, and flexural strength over the non-treated products, so it is demonstrated that a density increase and a strength increase are achieved. Because the sample sizes were different between those in Table 2 and those in Table 3, it was confirmed that there were differences in bulk density values between those in Table 2 and those in Table 3.

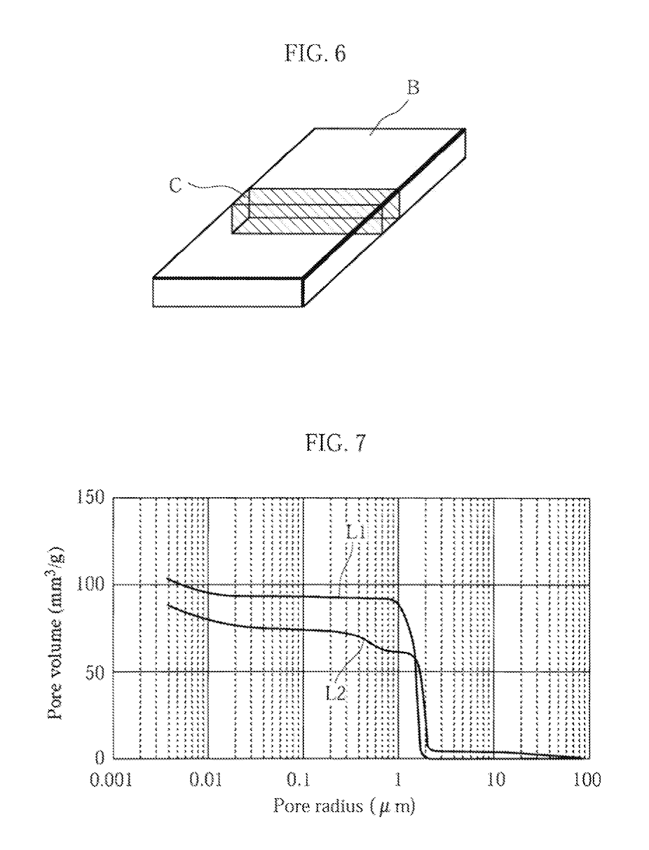

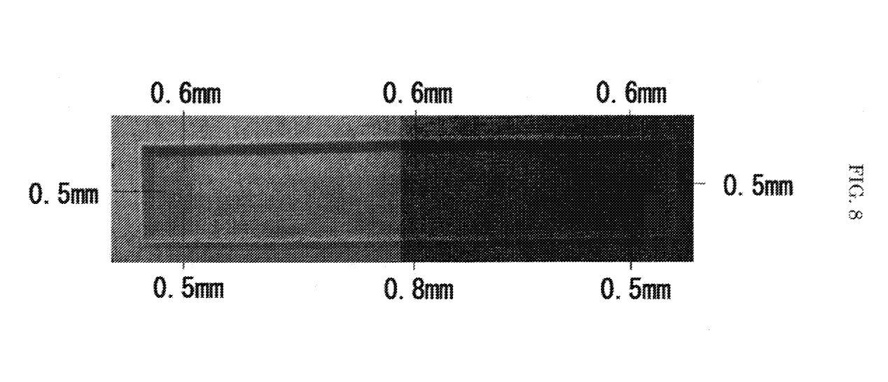

In addition, pore (open pore) distribution was studied as the physical properties before and after the surface treatment. The results of the measurement are shown in FIG. 7. The measurement method was as follows. A test specimen for the measurement was taken at about 2.4 mm in thickness from the surface layer of the present invention treated product, and the measurement was conducted for this test specimen for measurement.

In FIG. 7, L1 represents the distribution for the present invention treated product, and L2 represents the distribution for the non-treated product. As is clear from FIG. 7, the present invention treated product was smaller in volumetric capacity of the pores.

### Test Example 3

Mass changes and volumetric changes before and after the SiC reaction were investigated for test samples A and B that were subjected to the SiC formation reaction test of the foregoing Test Example 2.

(Test Results)

The results of the measurement of mass changes and volumetric changes before and after the SiC reaction test are shown in Table 4 below.

TABLE 4

| | Present invention | | | |
|---|---|---|---|---|
| | treated product | | Non-treated product | |
| | 10 × | 100 × | 10 × | 100 × |
| | 10 × 60 | 200 × 20 | 10 × 60 | 200 × 20 |
| | (mm) | (mm) | (mm) | (mm) |
| Mass change ratio | −4.9 | −1.0 | −4.4 | −0.9 |
| (%) | | | | |
| Volumetric change ratio | −4.3 | −0.9 | −5.0 | −1.8 |
| (%) | | | | |

(Evaluation of the Test Results)

As clearly seen from Table 4, it is observed that, in terms of mass change ratio, the non-treated products showed lower mass decreases than the present invention treated products, irrespective of the sizes of the samples. In addition, in terms of volumetric change ratio, the present invention treated products showed lower values than the non-treated products. The reactivity cannot be evaluated unconditionally based on the mass change ratio and the volumetric change ratio because a thickness reduction due to the reaction and a mass increase due to the SiC formation occur before and after the test. However, from the results, it is believed that the phenolic resin impregnating and curing treatment had the effect of inhibiting the SiC formation. In particular, considerable differences were not observed because the treatment time was a short time, 8 hours. However, it is believed that if the treatment time is set at about 100 hours, considerable differences will be observed and definitive evaluation will be made.

### Test Example 4

For test samples A to C that were subjected to the SiC reaction test in the same manner as in the foregoing Test Example 4, the thickness of the SiC layer after the reaction test was observed in the following two kinds of methods, (1) observation after ashing and (2) observation by scanning electron microscope.

(1) Observation after Ashing

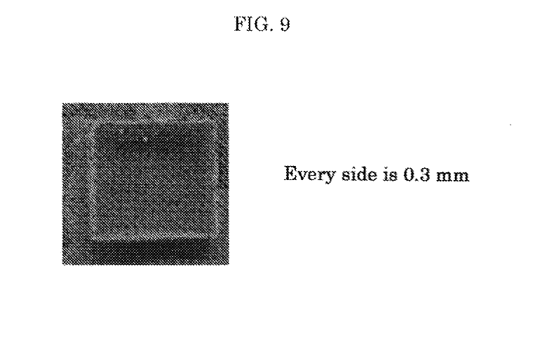

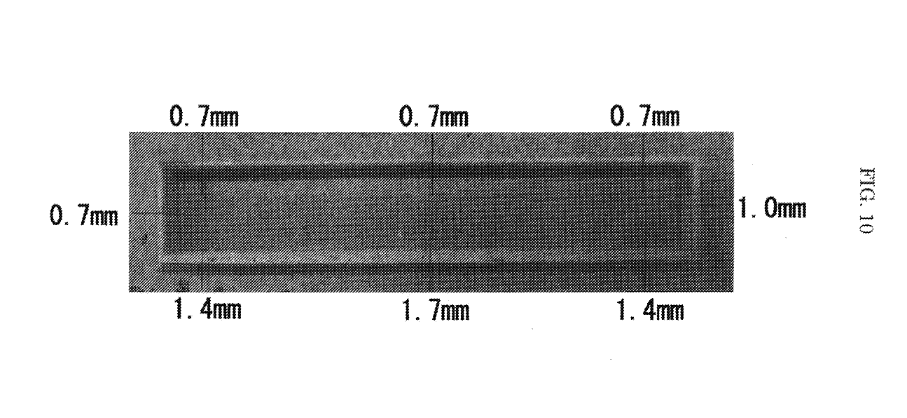

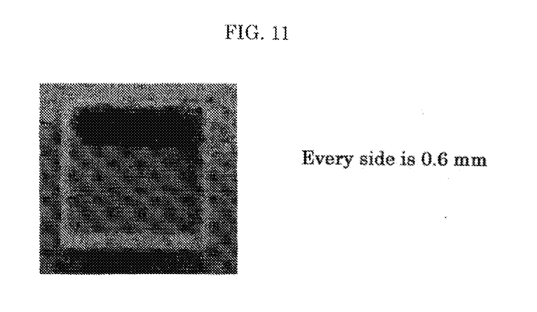

Using test samples A and B after the SiC reaction test, the remaining portion of the graphite material was incinerated and ashed under the air atmosphere at 800° C., and the thickness of the remaining SiC layer was investigated. The results are shown in Table 5. In addition, the conditions of test samples A and B after ashing are shown in FIGS. 8 to 11. Note that FIG. 8 is a photograph illustrating the condition of test sample A (present invention treated product) after ashing, FIG. 9 is a photograph illustrating the condition of test sample B (present invention treated product) after ashing, FIG. 10 is a photograph illustrating the condition of test sample A (non-treated product) after ashing, and FIG. 11 is a photograph illustrating the condition of test sample B (non-treated product) after ashing.

TABLE 5

| | Present invention | | | |
|---|---|---|---|---|
| | treated product | | Non-treated product | |
| | | 100 × | | 100 × |
| | 10 × 10 × 60 | 200 × 20 | 10 × 10 × 60 | 200 × 20 |
| | (mm) | (mm) | (mm) | (mm) |
| Maximum | 0.3 | 0.8 | 0.6 | 1.7 |
| SiC layer thickness | | | | |
| (mm) | | | | |
| Average | 0.3 | 0.6 | 0.6 | 1.0 |
| SiC layer thickness | | | | |
| (mm) | | | | |

(Evaluation of the Test Results)

As is clear from FIGS. 8 to 11 and Table 5, it is observed that the present invention treated products have greater effects of inhibiting SiC formation than the non-treated products. Although there are differences in the SiC layer values depending on the sample size, the present invention treated products had about 50% thinner SiC layers of those of the non-treated products.

(2) Observation by Scanning Electron Microscope (SEM)

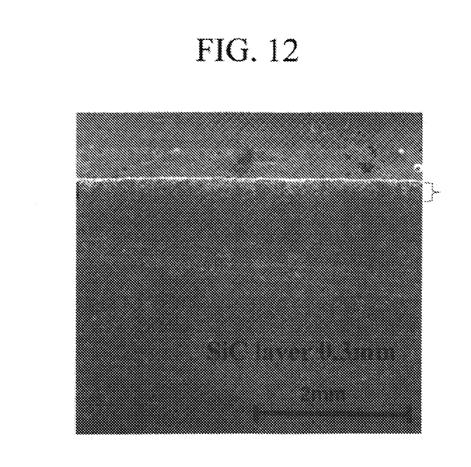

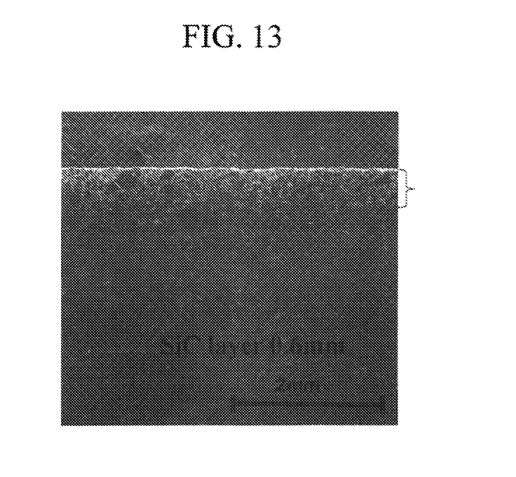

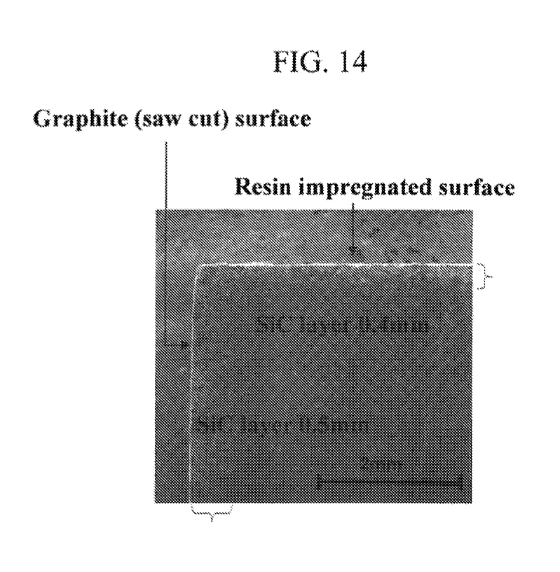

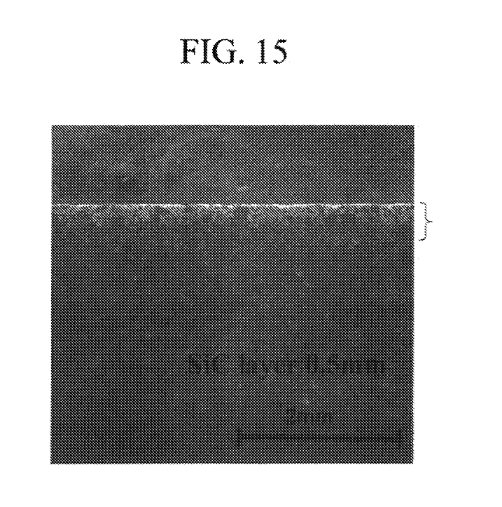

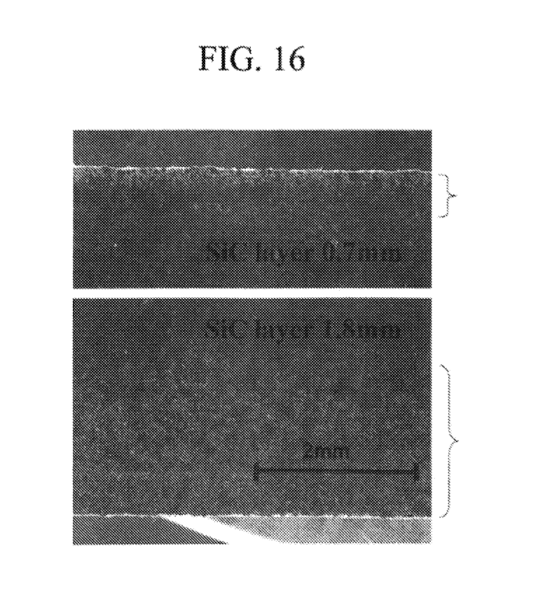

The SEM photographs concerning the surface conditions of test samples A to C after the SiC reaction test are shown in FIGS. 12 to 16. Note that FIG. 12 is a SEM photograph of test sample A (present invention treated product), FIG. 13 is a SEM photograph of test sample B (present invention treated product), FIG. 14 is a SEM photograph of test sample C (present invention treated product), FIG. 15 is a SEM photograph of test sample A (non-treated product), and FIG. 16 is a SEM photograph of test sample C (non-treated product). In FIGS. 12 to 16, the brace “}” indicates a SiC layer.

(Evaluation of the Test Results)

From the SEM photographs, the thickness of the SiC layer showed the same tendency as the results in ashing. It was confirmed that the present invention treated products have advantageous effects of inhibiting SiC formation over the non-treated products.

### Examples Corresponding to Embodiment 2

### Test Example 1

Dimensional changes were investigated for the following test samples.

(Test Sample)

A graphite material was surface-treated by the same CVI method as described in the foregoing embodiment 2. For two kinds of graphite materials, this surface-treated graphite material and a non-treated graphite material, samples with the following shape were prepared for testing.

Divided pieces of 3-piece graphite crucible: 1 piece for each Hereinbelow, a divided piece using the surface-treated graphite material is referred to as a present invention treated product, and a divided piece using the non-treated graphite material is referred to as a non-treated product.

(CVI Process)

The CVI process was carried out in the following manner. Specifically, the graphite material was placed in a vacuum furnace and the temperature was elevated to 1100° C. Thereafter, while CH₄ gas was being flowed at a flow rate 10 (L/min), the pressure was controlled to be 10 Torr and kept for 100 hours.

(Test Results)

The dimensional changes in height, inner diameters at 50 mm and 150 mm from the upper end of the crucible, and radius of the sharply curved portion were investigated for the present invention treated product and the non-treated product. The results are shown in Table 6.

TABLE 6

| | Non treated | | | |
|---|---|---|---|---|
| | product | Present invention treated product | | |
| | Size | Size | Variation | Change ratio |
| | mm | mm | mm | % |
| Height | 330.01 | 330.04 | 0.03 | 0.01 |
| Inner diameter | 459.08 | 459.13 | 0.05 | 0.01 |
| (50 mm from | | | | |
| upper end of crucible) | | | | |
| Inner diameter | 459.12 | 459.17 | 0.05 | 0.01 |
| (150 mm from | | | | |
| upper end of crucible) | | | | |
| Side face sharply | 120.00 | 120.03 | 0.03 | 0.03 |
| curved portion (radius) | | | | |

(Evaluation of the Test Results)

As is clear from Table 6, it was confirmed that the present invention treated product shows extremely small dimensional changes and that there is no problem at all in practical use.

### Test Example 2

A SiC formation reaction test was conducted for the following test samples to investigate changes in their physical properties (bulk density, hardness, electrical resistivity, flexural strength, and pore (open pore) distribution) before and after the SiC reaction.

(Test Sample)

Two kinds of samples, a present invention treated product and a non-treated product that were the same as those in Test Example 1 except for their shapes, were prepared as the test samples.

The samples with the following shapes were used as the test samples.

Rod-shaped sample with dimensions 10×10×60 (mm): Hereinbelow, this rod-shaped sample is referred to as test sample A1.

Plate-shaped sample with dimensions 100×200×20 (mm): Hereinbelow, this plate-shaped sample is referred to as test sample B1.

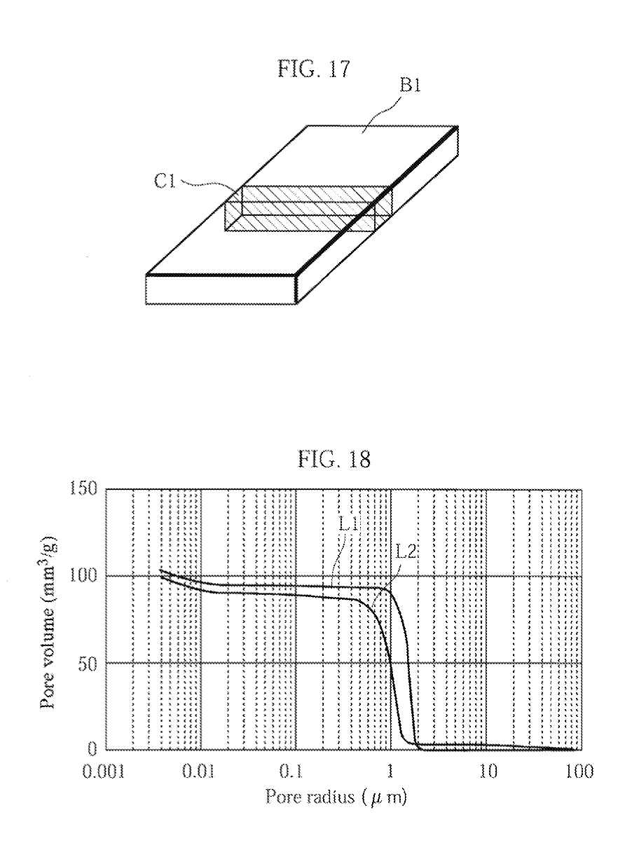

A cut-out piece obtained by cutting out a test specimen with dimensions 100×20×thickness 20 (mm) from test sample B1: (as illustrated in FIG. 17, out of six surfaces thereof, four surfaces are coated surfaces, and the remaining two surfaces are non-coated surfaces): Hereinbelow, this cut-out piece is referred to as test sample C1.

Test samples A1 and B1 are also used as the samples for later-described Test Examples 3 and 4, in addition to for this Test Example 2, and test sample C1 is used only for observation by scanning electron microscope (SEM) in the later-described Test Example 4.

Of test samples A1 to C1, ones that are surface-treated by the CVI method are referred to as present invention treated products, and ones that are not surface-treated are referred to as non-treated products.

(SiC Formation Reaction Test)

Test samples A to C were subjected to a high-temperature heat treatment with synthetic quartz (high purity SiO₂) to compare SiC formation reactivity. The specific conditions in this case are as follows.

Treating furnace: Vacuum furnace

Treatment temperature: 1600° C.

Furnace internal pressure: 10 Torr

Treatment gas: Ar 1 mL/min

Treatment time: Retained for 8 hours

Treatment method: Test samples are buried in synthetic quartz powder and heat-treated.

(Test Results)

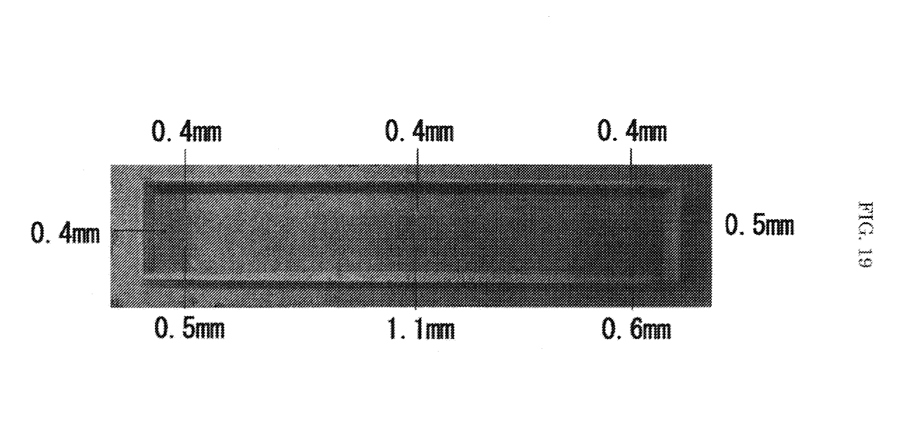

The physical properties (bulk density, hardness, electrical resistivity, and flexural strength) of test samples A1 and B1 were studied before and after the surface treatment. The results of the measurement are shown in Tables 7 and 8. The results of the measurement for pore (open pore) distribution are shown in FIG. 18.

TABLE 7

| | Present invention | |
|---|---|---|
| | treated product | Non-treated product |
| Bulk density | 1.77 | 1.74 |
| (Mg/m³) | | |
| Hardness | 65 | 55 |
| (HSD) | | |
| Electrical resistivity | 13.3 | 14.0 |
| (μΩm) | | |
| Flexural strength | 45 | 40 |
| (MPa) | | |

TABLE 8

| | Present invention treated product | Non-treated product |
|---|---|---|
| Bulk density | 1.76 | 1.75 |
| (Mg/m³) | | |

(Evaluation of the Test Results)

As is clear from Tables 7 and 8, the present invention treated products show improvements in all of bulk density, hardness, and flexural strength over the non-treated products, so it is demonstrated that a density increase and a strength increase are achieved. Because the sample sizes were different between those in Table 2 and those in Table 3, it was confirmed that there were differences in bulk density values between those in Table 2 and those in Table 3.

In addition, pore (open pore) distribution was studied as the physical properties before and after the surface treatment. The results of the measurement are shown in FIG. 18. The measurement method was as follows. A test specimen for the measurement was taken at about 2.4 mm in thickness from the surface layer of the present invention treated product, and the measurement was conducted for this test specimen for measurement.

In FIG. 18, L3 represents the distribution for the present invention treated product, and L4 represents the distribution for the non-treated product. As is clear from FIG. 18, the present invention treated product made the volumetric capacity of large pores smaller. The CVI made the size of the pores smaller.

### Test Example 3

Mass changes and volumetric changes before and after the SiC reaction were investigated for test samples A1 and B1 that were subjected to the SiC formation reaction test of the foregoing Test Example 2.

(Test Results)

The results of the measurement of mass changes and volumetric changes before and after the SiC reaction test are shown in Table 9 below.

TABLE 9

| | Present invention | | | |
|---|---|---|---|---|
| | treated product | | Non-treated product | |
| | | 100 × | | 100 × |
| | 10 × 10 × 60 | 200 × 20 | 10 × 10 × 60 | 200 × 20 |
| | (mm) | (mm) | (mm) | (mm) |
| Mass change ratio | −5.0 | −1.3 | −4.4 | −0.9 |
| (%) | | | | |
| Volumetric change | −5.0 | −1.0 | −5.0 | −1.8 |
| ratio (%) | | | | |

(Evaluation of the Test Results)

As clearly seen from Table 9, it is observed that, in terms of mass change ratio, the non-treated products showed less mass decreases than the present invention treated products, irrespective of the sizes of the samples. In addition, in terms of volumetric change ratio, the present invention treated products showed lower values than the non-treated products. The reactivity cannot be evaluated unconditionally based on the mass change ratio and the volumetric change ratio because a thickness reduction due to the reaction and a mass increase due to the SiC formation occur before and after the test. However, from the results, it is believed that the CVI process had the effect of inhibiting the SiC formation. In particular, considerable differences were not observed because the treatment time was a short time, 8 hours. However, it is believed that if the treatment time is set at about 100 hours, considerable differences will be observed and definitive evaluation will be made.

### Test Example 4

For test samples A1 to C1 that were subjected to the SiC reaction test in the same manner as in the foregoing Test Example 4, the thickness of the SiC layer after the reaction test was observed in the following two kinds of methods, (1) observation after ashing and (2) observation by scanning electron microscope.

(1) Observation after Ashing

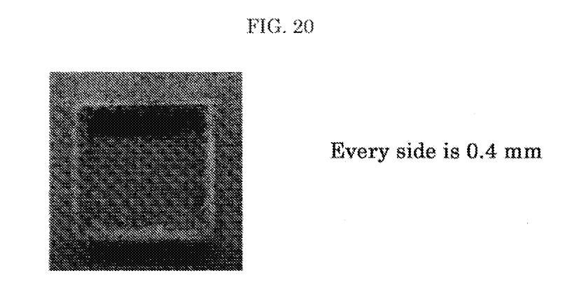

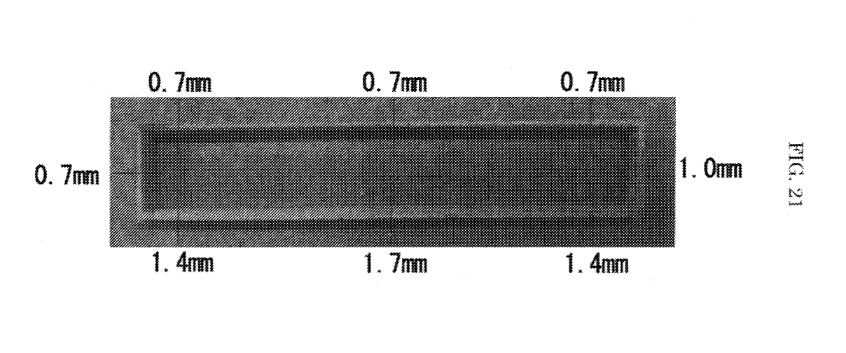

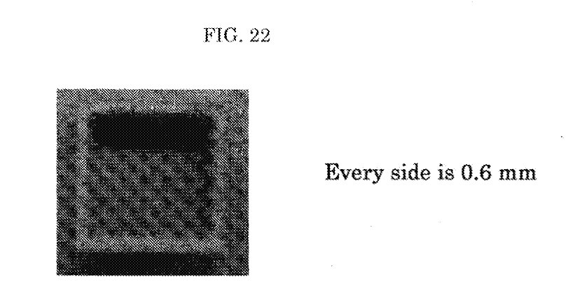

The remaining portions of the graphite material in test samples A and B after the SiC reaction test were incinerated and ashed under the air atmosphere at 800° C., and the thickness of the remaining SiC layer was investigated. The results are shown in Table 10. In addition, the conditions of test samples A1 and B1 after ashing are shown in FIGS. 19 to 22. Note that FIG. 19 is a photograph illustrating the condition of test sample A1 (present invention treated product) after ashing, FIG. 20 is a photograph illustrating the condition of test sample B1 (present invention treated product) after ashing, FIG. 21 is a photograph illustrating the condition of test sample A1 (non-treated product) after ashing, and FIG. 22 is a photograph illustrating the condition of test sample B1 (non-treated product) after ashing.

TABLE 10

| | Present invention | | | |
|---|---|---|---|---|
| | treated product | | Non-treated product | |
| | | 100 × | | 100 × |
| | 10 × 10 × 60 | 200 × 20 | 10 × 10 × 60 | 200 × 20 |
| | (mm) | (mm) | (mm) | (mm) |
| Maximum | 0.4 | 1.1 | 0.6 | 1.7 |
| SiC layer thickness | | | | |
| (mm) | | | | |
| Average | 0.4 | 0.5 | 0.6 | 1.0 |
| SiC layer thickness | | | | |
| (mm) | | | | |

(Evaluation of the Test Results)

As is clear from FIGS. 19 to 22 and Table 10, it is observed that the present invention treated products have greater effects of inhibiting SiC formation than the non-treated products. Although there are differences in the SiC layer values depending on the sample size, the present invention treated products had about 50% thinner SiC layers of those of the non-treated products.

(2) Observation by Scanning Electron Microscope (SEM)

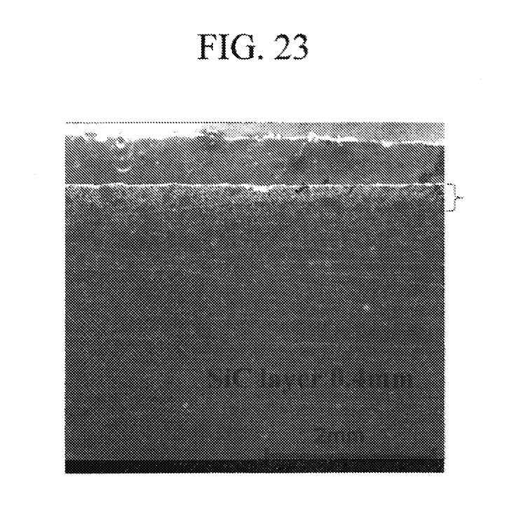

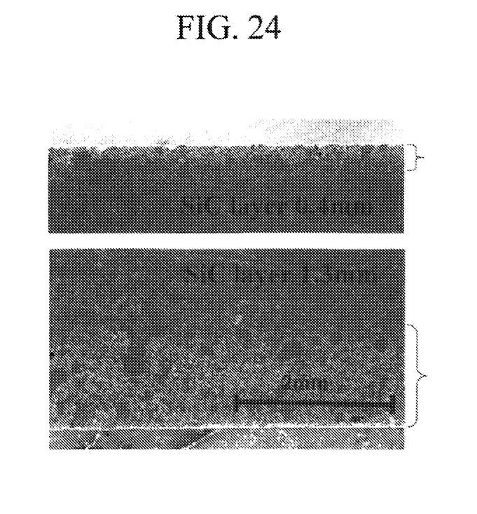

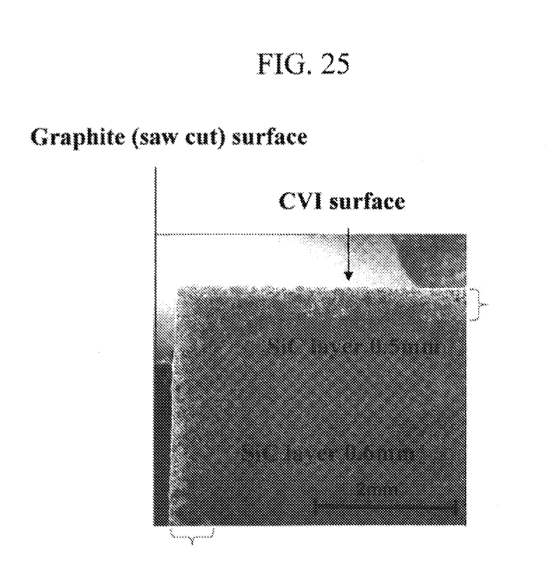

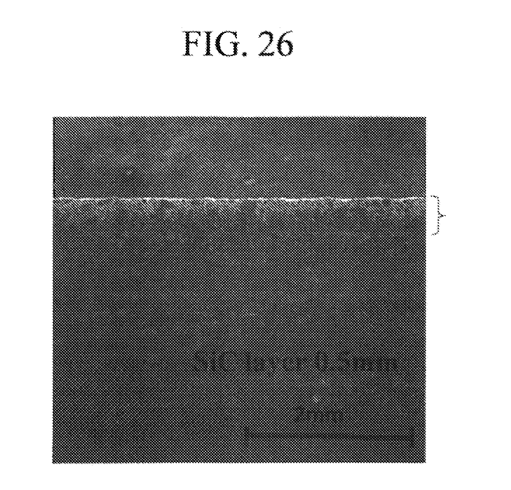

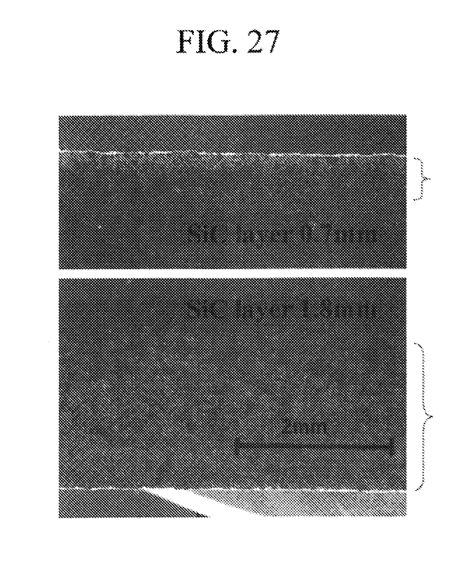

The SEM photographs concerning the surface conditions of test samples A1 to C1 after the SiC reaction test are shown in FIGS. 23 to 27. Note that FIG. 23 is a SEM photograph of test sample A1 (present invention treated product), FIG. 24 is a SEM photograph of test sample B1 (present invention treated product), FIG. 25 is a SEM photograph of test sample C1 (present invention treated product), FIG. 26 is a SEM photograph of test sample A1 (non-treated product), and FIG. 27 is a SEM photograph of test sample C1 (non-treated product). In FIGS. 23 to 27, the brace “}” indicates a SiC layer.

(Evaluation of the Test Results)

From the SEM photographs, the thickness of the SiC layer showed the same tendency as the results in ashing. It was confirmed that the present invention treated products have advantageous effects over the non-treated products.

### INDUSTRIAL APPLICABILITY

The present invention is applicable to a graphite crucible for single crystal pulling apparatus, and to a method of manufacturing the crucible.

### REFERENCE SIGNS LIST

1—Quartz crucible
2—Graphite crucible
3—Graphite crucible substrate
4—Phenolic resin coating film
4A—Pyrocarbon coating film
5—Open pore

1-12. (canceled)

13. A graphite crucible for single crystal pulling apparatus, characterized in that a phenolic resin impregnated in open pores existing in a surface of a graphite crucible substrate is carbonized.

14. The graphite crucible for single crystal pulling apparatus according to claim 13, wherein a coating film of the carbonized phenolic resin has an average thickness of 10 μm or less.

15. A method of manufacturing a graphite crucible for single crystal pulling apparatus, characterized by comprising the steps of:
immersing a graphite crucible substrate in a phenolic resin solution under room temperature and normal pressure;
curing the phenolic resin by taking out and heat-treating the immersed graphite crucible substrate; and
carbonizing the phenolic resin by subjecting the cured phenolic resin to a further heat treatment.

16. The method of manufacturing a graphite crucible for single crystal pulling apparatus according to claim 15, further comprising, prior to the curing step, the step of wiping off an excessive amount of the phenolic resin on a surface of the graphite crucible substrate.

17. The method of manufacturing a graphite crucible for single crystal pulling apparatus according to claim 16, wherein the phenolic resin solution has a viscosity of from 100 mPa·s (18° C.) to 400 mPa·s (18° C.).

18. The method of manufacturing a graphite crucible for single crystal pulling apparatus according to claim 15, further comprising, subsequent to the curing step, the step of performing a heat treatment at a temperature equal to or higher than a service temperature.

19. The method of manufacturing a graphite crucible for single crystal pulling apparatus according to claim 15, further comprising, subsequent to the curing step, the step of refining the graphite crucible substrate on which a coating film of the phenolic resin is formed, by heat-treating the graphite crucible substrate under a halogen gas atmosphere.

20. A graphite crucible for single crystal pulling apparatus, characterized in that a coating film of pyrocarbon is formed on an entirety of or a portion of a surface of a graphite crucible substrate, and the coating film is formed so as to reach an inner surface of open pores existing in the surface of the graphite crucible substrate.

21. The graphite crucible for single crystal pulling apparatus according to claim 20, wherein the coating film has an average thickness of 100 μm or less.

22. The graphite crucible for single crystal pulling apparatus according to claim 20, wherein the coating film is formed by a CVI method.

23. The graphite crucible for single crystal pulling apparatus according to claim 21, wherein the coating film is formed by a CVI method.

24. A method of manufacturing a graphite crucible for single crystal pulling apparatus, characterized by comprising the step of forming a coating film of pyrocarbon by a CVI method so that the coating film of pyrocarbon is formed on an entirety of or a portion of a surface of a graphite crucible substrate and that the coating film is formed so as to reach an internal surface of open pores existing in a surface of the graphite crucible substrate.

25. The method of manufacturing a graphite crucible for single crystal pulling apparatus according to claim 24, further comprising the step of refining the graphite crucible substrate on which the coating film of pyrocarbon is formed by the pyrocarbon coating film formation step, by heat-treating the graphite crucible substrate under a halogen gas atmosphere.
